(19) United States
(12) Patent Application Publication
(10) Pub. No.: US 2026/0239988 A1
(43) Pub. Date: Aug. 13, 2026

(54) SEMICONDUCTOR PACKAGE

(71) Applicant: InnoLux Corporation, Miao-Li County (TW)

(72) Inventors: Wen-Bin HUNG, Miao-Li County (TW); Jui-Jen YUEH, Miao-Li County (TW); Ti-Chung CHANG, Miao-Li County (TW)

(21) Appl. No.: 19/440,788

(22) Filed: Jan. 6, 2026

(30) Foreign Application Priority Data
Feb. 10, 2025 (CN) 202510145172.6

(51) Int. Cl. H10W 42/00; H10W 72/00; H10W 74/10; H10W 90/20; H10W 90/28

(52) U.S. Cl. CPC H10W 42/121; H10W 72/823; H10W 74/111; H10W 90/275; H10W 90/28

(57) ABSTRACT

A semiconductor package is provided. The semiconductor package includes a first die, a first interconnection layer, and an encapsulation layer. The first die includes a first portion and a second portion. The first portion has a first surface and the second portion has a second surface. The first interconnection layer is disposed on the second surface. The encapsulation layer surrounds the first die and the first interconnection layer. In a cross-sectional view, the first portion has a first width at the first surface, and the second portion has a second width at the interface between the first portion and second portion. In addition, the second width is greater than the first width.

### CROSS REFERENCE TO RELATED APPLICATIONS

This application claims the benefit of China Application No. 202510145172.6, filed February 10, 2025, the entirety of which is incorporated by reference herein.

### BACKGROUND

### Technical Field

The present disclosure is related to an electronic device, and in particular it is related to an electronic device having a semiconductor package.

### Description of the Related Art

Packaging technology can increase the integration density of electronic components (e.g., transistors, diodes, resistors, capacitors, etc.) within a given area and has been widely used in the production and manufacturing of electronic devices in recent years. As semiconductor packaging sizes become smaller and smaller, the reliability requirements for chip manufacturing and packaging technology are also becoming increasingly higher.

Semiconductor packaging has many interface integration structures (e.g., the interface between the die and the encapsulation layer, the interface between the insulation layer and the encapsulation layer, etc.). During the bonding process, heterogeneous materials or flat interface structures can easily cause stress concentration, resulting in delamination, peeling, or cracking, which can affect the performance and reliability of the semiconductor package.

As mentioned above, developing structural designs that can improve the reliability of semiconductor packaging (e.g., improving the stability or strength of the packaging structure) remains one of the current research topics in the industry.

### SUMMARY

In some embodiments of the present disclosure, a semiconductor package is provided. The semiconductor package includes a first die, a first interconnection layer, and an encapsulation layer. The first die includes a first portion and a second portion. The first portion has a first surface and the second portion has a second surface. The first interconnection layer is disposed on the second surface. The encapsulation layer surrounds the first die and the first interconnection layer. In a cross-sectional view, the first portion has a first width at the first surface, and the second portion has a second width at an interface between the first portion and second portion. In addition, the second width is greater than the first width.

### BRIEF DESCRIPTION OF THE DRAWINGS

FIG. 1 is a cross-sectional diagram of a semiconductor package in some embodiments of the present disclosure;

FIGS. 2A to 2D respectively are enlarged diagrams of area A1, A2, A3 and A4 in FIG. 1 in some embodiments of the present disclosure;

FIGS. 3 and FIG. 4 are cross-sectional diagrams of a semiconductor package in some embodiments of the present disclosure.

### DETAILED DESCRIPTION

In some embodiments, the provided semiconductor package can be used, for example, in a wafer-level package (WLP) or panel-level package (PLP) process, and can adopt a chip-first process or a chip-last (RDL)-first process. Furthermore, in some embodiments, the semiconductor package may include a system on chip (SoC), a system in package (SiP), a chip on wafer on substrate (CoWoS) package, a system on integrated chip (SoIC), an antenna in package (AiP), co-packaged optics (CPO), a micro electromechanical system (MEMS), or a combination thereof.

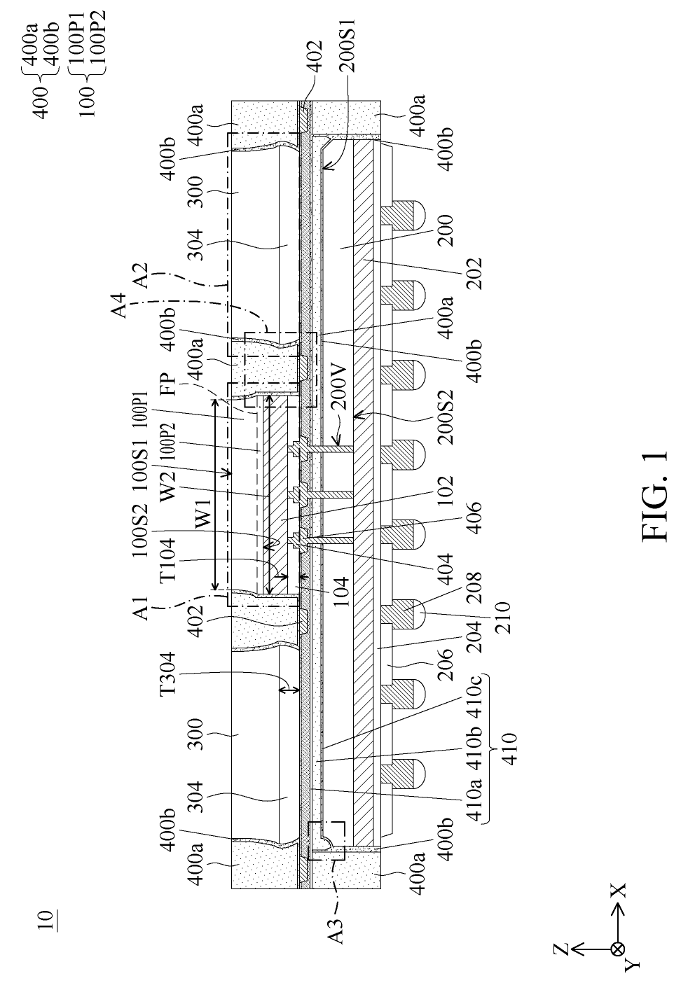

Referring to FIG. 1, which is a cross-sectional diagram of a semiconductor package 10 in some embodiments of the present disclosureAs shown in FIG. 1, a semiconductor package 10 may include a first die 100, a first interconnection layer 102, and an encapsulation layer 400. The first die 100 may be disposed on the first interconnection layer 102, and the encapsulation layer 400 may surround the first die 100 and the first interconnection layer 102.

The first die 100 may include a first portion 100P1 and a second portion 100P2. The first portion 100P1 has a first surface 100S1, and the second portion 100P2 has a second surface 100S2. The first surface 100S1 may be opposite to the second surface 100S2. In some embodiments, the second surface 100S2 is closer to the first interconnection layer 102 than the first surface 100S1. Furthermore, the second surface 100S2 may be an active surface of the first die 100, which may include a plurality of active devices.

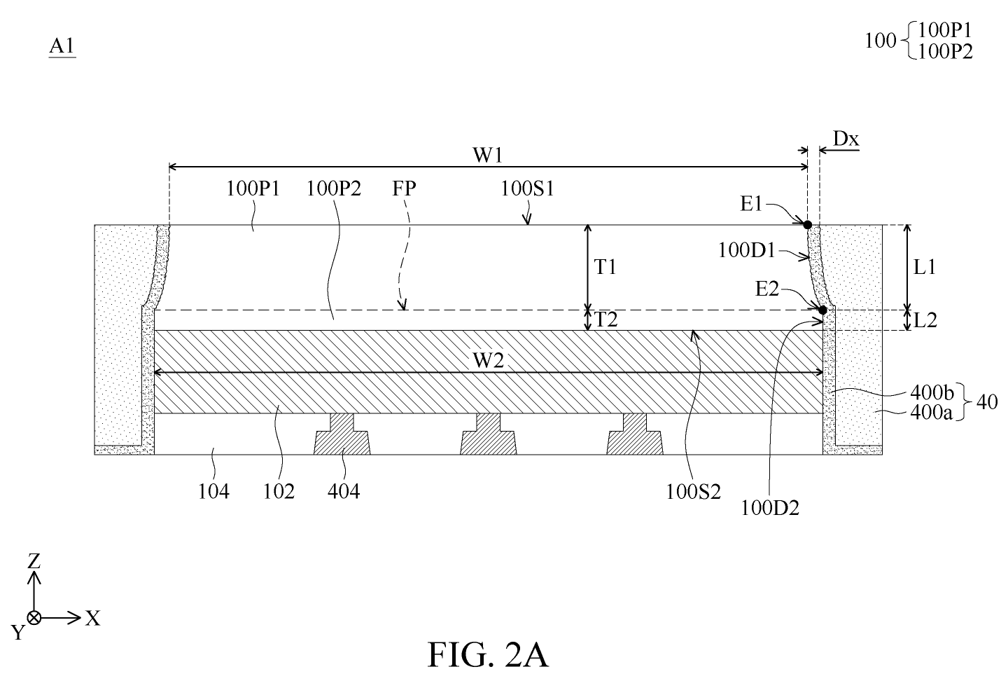

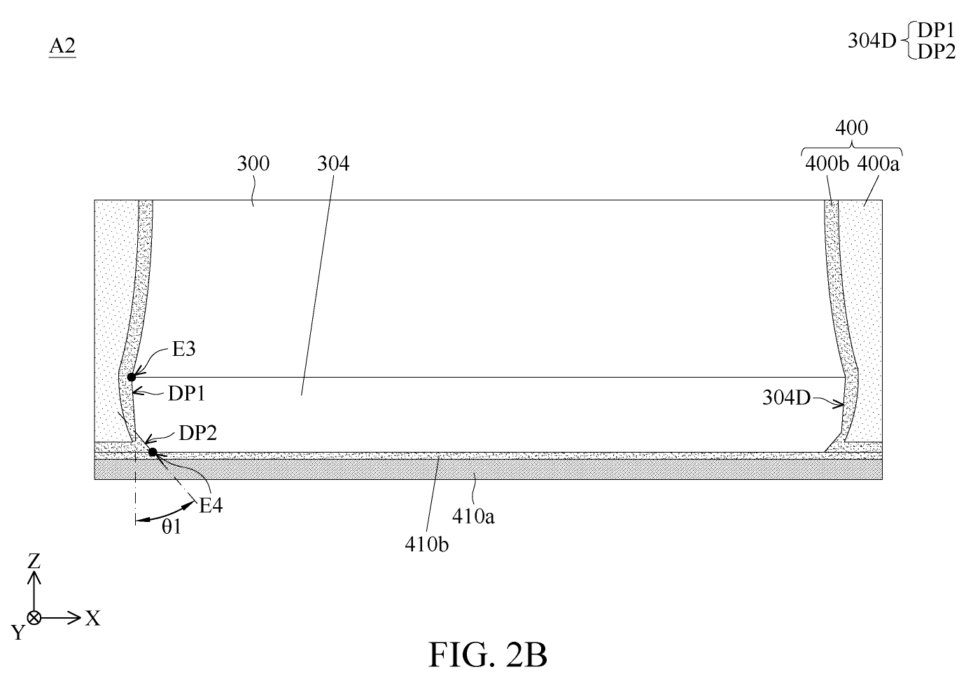

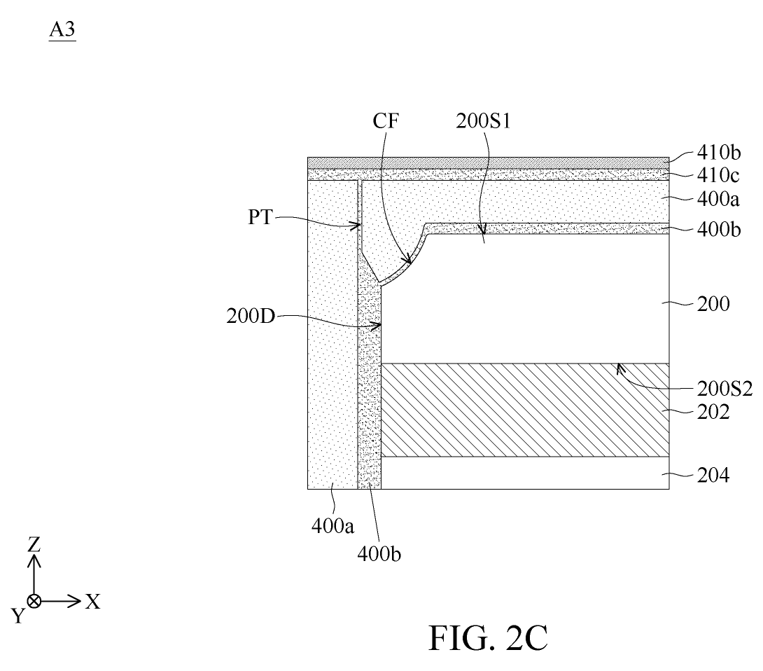

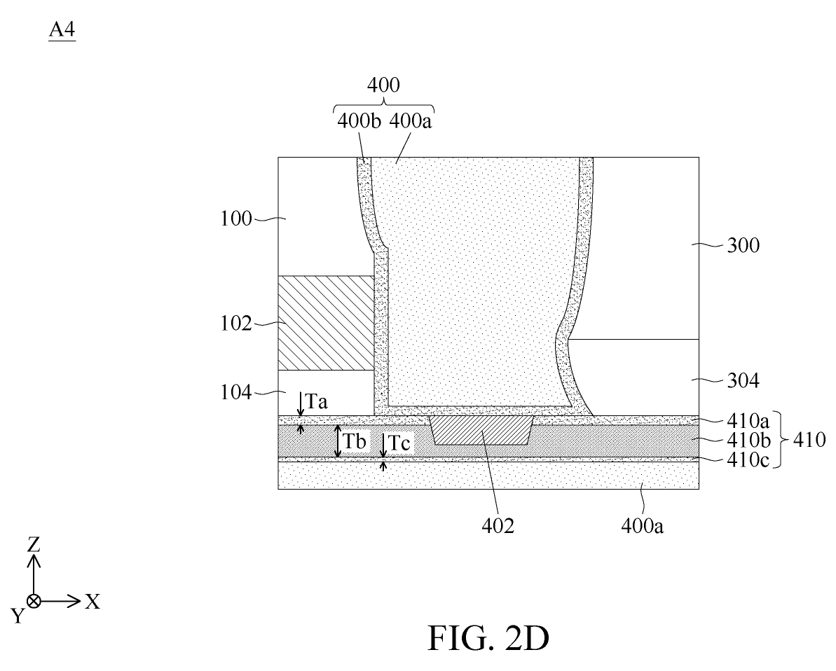

Specifically, please refer to FIGS. 1 and FIG. 2A. FIG. 2A is an enlarged diagram of area A1 in FIG. 1 in some embodiments of the present disclosure. In a cross-sectional view, the first portion 100P1 has a first width W1 at the first surface 100S1, and the second portion 100P2 has a second width W2 at an interface FP between the first portion 100P1 and the second portion 100P2. The second width W2 is greater than the first width W1. Furthermore, in some embodiments, a difference DX between the first width W1 and the second width W2 of the first die 100 may be between 0.1 μm and 1 μm (i.e., 0.1 μm ≤ difference DX ≤ 1 μm), for example, 0.2 μm, 0.3 μm, 0.4 μm, 0.5 μm, 0.6 μm, 0.7 μm, 0.8 μm, or 0.9 μm. Furthermore, in some embodiments, a thickness T1 of the first portion 100P1 of the first die 100 is greater than a thickness T2 of the second portion 100P2. The aforementioned thickness T1 refers to the maximum thickness of the first portion 100P1 in the normal direction of the first die 100 (e.g., the Z direction in the figure); and the thickness T2 refers to the maximum thickness of the second portion 100P2 in the normal direction of the first die 100.

It is worth noting that, through the aforementioned configuration, the interface between the first die 100 and the encapsulation layer 400 can be displaced away from the body of the first die 100 in a direction toward the first interconnection layer 102. As a result, stress can be guided in a direction away from the first interconnection layer 102, thereby reducing the risk that interfacial delamination, peeling, or crack propagation extends to the first interconnection layer 102.

Furthermore, as shown in FIG. 2A, in some embodiments, the first portion 100P1 of the first die 100 has a first side surface 100D1, and the second portion 100P2 of the first die 100 has a second side surface 100D2. The first side surface 100D1 and the second side surface 100D2 are disposed between the first surface 100S1 and the second surface 100S2. In some embodiments, the roughness of the first side surface 100D1 is greater than the roughness of the second side surface 100D2.

Furthermore, in some embodiments, in a thickness direction (or in a normal direction of the first die 100, such as the Z direction in the figure), a length L1 of the first side surface 100D1 is greater than a length L2 of the second side surface 100D2. In some embodiments, the length L1 of the first side surface 100D1 may be between 3 μm and 100 μm (i.e., 3 μm ≤ length L1 ≤ 100 μm), or between 3 μm and 50 μm, for example, 6 μm, 10 μm, 15 μm, 20 μm, 25 μm, 30 μm, 35 μm, 40 μm, or 45 μm. In some embodiments, the length L2 of the second side surface 100D2 may be between 0.1 μm and 1 μm (i.e., 0.1 μm ≤ length L2 ≤ 1 μm), for example, 0.2 μm, 0.3 μm, 0.4 μm, 0.5 μm, 0.6 μm, 0.7 μm, 0.8 μm, or 0.9 μm. In some embodiments, in a cross-sectional view, the first side surface 100D1 has a first end E1 located at the first surface 100S1 and a second end E2 located at the interface FP between the first side surface 100D1 and the second side surface 100D2 . The first end E1 is receded inward with respect to the second end E2.

As described above, the interface between the first die 100 and the encapsulation layer 400 (e.g., the first side surface 100D1) is displaced away from the body of the first die 100 in the direction toward the first interconnection layer 102. This allows stress to be directed away from the first interconnection layer 102, thereby reducing the risk of interface delamination, peeling, or cracks extending to the first interconnection layer 102.

In some embodiments, the first die 100 may include a known-good die (KGD), an integrated circuit chip (IC), or another suitable electronic component. In some embodiments, the first die 100 may be an auxiliary chip. Specifically, in some embodiments, the first die 100 may include a system-on-chip, a dynamic random-access memory, a high-bandwidth memory, a photonic integrated circuit, an application-specific integrated circuit, an active component, a passive component, a power management system-on-chip, or other logic integrated circuits.

Still refer to FIGS. 1 and FIG. 2A, the first interconnection layer 102 may be disposed on the second surface 100S2 of the second portion 100P2 of the first die 100. The first interconnection layer 102 may be electrically connected to the first die 100. In some embodiments, the first interconnection layer 102 may include relevant circuit lines and signal lines required by the first die 100.

The first interconnection layer 102 may have one or more dielectric layers and patterned conductive layers. In some embodiments, the dielectric layer of the first interconnection layer 102 may include a polymer dielectric insulating material, such as polybenzoxazole (PBO), polyimide, benzocyclobutene (BCB), another suitable polymer dielectric material, or a combination thereof. In other embodiments, the dielectric layer of the first interconnection layer 102 may include silicon nitride (SiNx), silicon oxide (SiOx), silicon oxynitride (SiON), phosphosilicate glass (PSG), borosilicate glass (BSG), boron-doped phosphosilicate glass (BPSG), another suitable dielectric material, or a combination thereof. In some embodiments, the material of the patterned conductive layer of the first interconnection layer 102 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof.

As described above, the encapsulation layer 400 may surround the first die 100 and the first interconnection layer 102. In some embodiments, the encapsulation layer 400 may have a multi-layer structure, for example, including a first sublayer 400a and a second sublayer 400b. The second sublayer 400b may be disposed between the first die 100 and the first sublayer 400a, and between the first interconnection layer 102 and the first sublayer 400a. In some embodiments, the encapsulation layer 400 may be in contact with the first die 100 and the first interconnection layer 102. For example, the second sublayer 400b may be in contact with the first die 100 and the first interconnection layer 102. The encapsulation layer 400 can reduce the impact of moisture and oxygen on the first die 100 and the first interconnection layer 102, reduce impact damage to the first die 100 and the first interconnection layer 102, enhance the mechanical stability of the structure, or provide a heat dissipation path.

In some embodiments, the materials of the first sublayer 400a and the second sublayer 400b of the encapsulation layer 400 may include silicon oxide (SiOx), silicon nitride (SiNx), silicon oxynitride (SiON), aluminum oxide, phosphosilicate glass (PSG), borosilicate glass (BSG), boron-doped phosphosilicate glass (BPSG), undoped silicon glass (USG), polybenzoxazole (PBO), benzocyclobutene (BCB), another suitable encapsulation material, or a combination thereof. The first sublayer 400a and the second sublayer 400b of the encapsulation layer 400 may be formed of different materials. In some embodiments, the first sublayer 400a may include silicon oxide, and the second sublayer 400b may include silicon nitride.

Still referring to FIG. 1, the semiconductor package 10 may further include a second die 200 and a structural die 300. The first die 100 may be disposed on the second die 200. The structural die 300 may be disposed on the second die 200 and adjacent to the first die 100. The first die 100 is electrically connected to the second die 200, and the structural die 300 is electrically insulated from the second die 200. In some embodiments, the encapsulation layer 400 may surround the second die 200 and the structural die 300. In some embodiments, the encapsulation layer 400 may be disposed between the second die 200 and the structural die 300. The encapsulation layer 400 may also be disposed between the second die 200 and the first die 100. In some embodiments, the encapsulation layer 400 may be in contact with the first die 100, the second die 200, and the structural die 300.

In some embodiments, the size of the second die 200 may be larger than the sizes of the first die 100 and the structural die 300. In some embodiments, in the normal direction of the second die 200, the second die 200 may overlap with the first die 100 and the structural die 300. For example, one second die 200 may overlap with one first die 100 and two structural dies 300, but the present disclosure is not limited thereto. It should be understood that the number of first dies 100, second dies 200, and structural dies 300 is not limited to that shown in the figure. In other embodiments, the semiconductor package 10 may have other suitable numbers of first dies 100, second dies 200, and structural dies 300.

In some embodiments, the second die 200 may include a known-good die (KGD), an integrated circuit chip (IC), or another suitable electronic component. In some embodiments, the second die 200 may be a computing chip, such as a central processing unit (CPU), a graphics processing unit (GPU), or another digital logic circuit.

In some embodiments, the structural die 300 may serve as a dummy die that is not electrically connected to other components, but rather provides structural support and heat dissipation. In some embodiments, the structural die 300 may be disposed on both sides of the first die 100. In some embodiments, the structural die 300 may include bulk semiconductor, glass, sapphire, ceramic, or another suitable material.

Please refer to FIGS. 1 and FIG. 2B. FIG. 2B is an enlarged diagram of area A2 in FIG. 1 in some embodiments of the present disclosure. In some embodiments, the semiconductor package 10 may further include an insulating layer 304. The insulating layer 304 may be disposed between the structural die 300 and the second die 200, and the encapsulation layer 400 may contact the side surface 304D of the insulating layer 304. In some embodiments, the encapsulation layer 400 may surround the structural die 300 and the insulating layer 304. Specifically, the second sublayer 400b of the encapsulation layer 400 may contact the side surface 304D of the insulating layer 304. In some embodiments, in a cross-sectional view, the side surface 304D of the insulating layer 304 includes a third end E3 in contact with the structural die 300 and a fourth end E4 away from the third end E3, with the fourth end E4 receded inward with respect to the third end E3. Furthermore, in some embodiments, the side surface 304D of the insulating layer 304 includes a first portion DP1 connected to the third end E3 and a second portion DP2 connected to the fourth end E4, with the second portion DP2 forming an angle θ1 with the first portion DP1. In some embodiments, the angle θ1 may be between 1 degree and 45 degrees, for example, 5 degrees, 10 degrees, 15 degrees, 20 degrees, 25 degrees, 30 degrees, 35 degrees, or 40 degrees.

In other words, the side surface 304D of the insulating layer 304 has at least one inwardly angled profile. It is noteworthy that the inwardly concave and angled profile of the interface between the insulating layer 304 and the encapsulation layer 400 (e.g., the side surface 304D) can alleviate excessive stress concentration at the interface, thereby reducing the risk of interface delamination, peeling, or cracking.

In some embodiments, the material of the insulating layer 304 may include silicon oxide, silicon nitride, silicon oxynitride, aluminum oxide, another suitable insulating material, or a combination thereof.

Referring again to FIG. 1, in some embodiments, the semiconductor package 10 may further include a second interconnection layer 202. The second interconnection layer 202 may be electrically connected to the second die 200. In some embodiments, the second interconnection layer 202 may include relevant circuit lines and signal lines required by the second die 200. The second die 200 may have a surface 200S1 adjacent to the first die 100 and a surface 200S2 away from the first die 100. The surface 200S2 may be the active surface of the second die 200 and may include a plurality of active devices. The second interconnection layer 202 may be disposed on the surface 200S2 of the second die 200 that is away from the first die 100. The first interconnection layer 102 may be electrically connected to the second interconnection layer 202 through a conductive via 200V in the second die 200. Furthermore, in some embodiments, the encapsulation layer 400 may surround the second die 200 and the second interconnection layer 202.

The second interconnection layer 202 may include one or more dielectric layers and patterned conductive layers. In some embodiments, the dielectric layer of the second interconnection layer 202 may include a polymer dielectric insulating material, such as polybenzoxazole (PBO), polyimide, benzocyclobutene (BCB), another suitable polymer dielectric material, or a combination thereof. In other embodiments, the dielectric layer of the second interconnection layer 202 may include silicon nitride, silicon oxide, silicon oxynitride, phosphosilicate glass (PSG), borosilicate glass (BSG), boron-doped phosphosilicate glass (BPSG), another suitable dielectric material, or a combination thereof. In some embodiments, the material of the patterned conductive layer of the second interconnection layer 202 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof.

In some embodiments, the semiconductor package 10 may further include a first bonding layer 404 and a second bonding layer 406. The first bonding layer 404 may be disposed on the first interconnection layer 102. The second bonding layer 406 may be disposed on the surface 200S1 of the second die 200 adjacent to the first die 100. The first bonding layer 404 may be directly bonded to the second bonding layer 406. In some embodiments, the first interconnection layer 102 may be electrically connected to the conductive via 200V in the second die 200 through the first bonding layer 404 and the second bonding layer 406, thereby electrically connecting to the second interconnection layer 202. In some embodiments, the first die 100 and the second die 200 can be bonded together through the first bonding layer 404 and the second bonding layer 406. For example, the first die 100 and the second die 200 may be bonded together through a hybrid bonding process.

The first bonding layer 404 and the second bonding layer 406 may include a metal material. In some embodiments, the metal material may include copper (Cu), gold (Au), nickel (Ni), silver (Ag), titanium (Ti), aluminum (Al), alloys of the aforementioned metals, another suitable metal material, or a combination thereof.

In addition, in some embodiments, the semiconductor package 10 may further include an insulating layer 104. The insulating layer 104 may be disposed between the first die 100 and the second die 200, and the first bonding layer 404 may penetrate the insulating layer 104. In some embodiments, the encapsulation layer 400 may surround the insulating layer 104. The insulating layer 104 may contact the encapsulation layer 400. For example, the insulating layer 104 may contact the second sublayer 400b of the encapsulation layer 400. In some embodiments, a thickness T104 of the insulating layer 104 may be less than a thickness T304 of the insulating layer 304. The aforementioned thickness T104 refers to the maximum thickness of the insulating layer 104 in the normal direction of the first die 100 (for example, the Z direction in the figure); and the thickness T304 refers to the maximum thickness of the insulating layer 304 in the normal direction of the structural die 300 (for example, the Z direction in the figure).

In some embodiments, the material of the insulating layer 104 may include silicon oxide, silicon nitride, silicon oxynitride, aluminum oxide, another suitable insulating material, or a combination thereof.

Next, please refer to FIGS. 1 and FIG. 2C. FIG. 2C is an enlarged diagram of area A3 in FIG. 1 in some embodiments of the present disclosure. In some embodiments, the second die 200 includes the surface 200S1 and the side surface 200D adjacent to the first die 100, and a chamfer CF is formed between the surface 200S1 and the side surface 200D. In some embodiments, in the cross-sectional view, the chamfer CF includes a curved edge. In some embodiments, the second sublayer 400b of the encapsulation layer 400 may contact the surface 200S1, the side surface 200D, and the chamfer CF of the second die 200. In some embodiments, the thickness of the encapsulation layer 400 (second sublayer 400b) in contact with the chamfer CF is different from the thickness of the encapsulation layer 400 (second sublayer 400b) in contact with the surface 200S1. The thickness of the encapsulation layer 400 (second sublayer 400b) in contact with the chamfer CF is also different from the thickness of the encapsulation layer 400 (second sublayer 400b) in contact with the side surface 200D. In some embodiments, the thickness of the second sublayer 400b in contact with the chamfer CF is less than the thickness of the second sublayer 400b in contact with the surface 200S1. In some embodiments, the thickness of the second sublayer 400b in contact with the chamfer CF is less than the thickness of the second sublayer 400b in contact with the side surface 200D. Furthermore, in some embodiments, the second sublayer 400b adjacent to the chamfer CF but not in contact with the second die 200 has an extended profile PT. The extended profile PT may include silicon nitride, which can enhance protection of the second die 200, for example, by blocking moisture.

It is noteworthy that, by configuring the aforementioned chamfer CF, the interface between the second die 200 and the encapsulation layer 400 has a curved chamfer, which can reduce excessive stress concentration at this location, thereby reducing the risk of interface delamination, peeling, or cracking.

Next, please refer to FIGS. 1 and FIG. 2D. FIG. 2D is an enlarged diagram of area A4 in FIG. 1 in some embodiments of the present disclosure. In some embodiments, the semiconductor package 10 may further include a composite structure 410. The composite structure 410 may be disposed between the second die 200 and the combination of the first die 100 and the structural die 300. That is, the composite structure 410 may be disposed between the second die 200 and the first die 100, and the composite structure 410 may also be disposed between the second die 200 and the structural die 300. In some embodiments, composite structure 410 may include a first silicon nitride layer 410a, a silicon oxide layer 410b, and a second silicon nitride layer 410c. The second silicon nitride layer 410c is closer to the second die 200 than the first silicon nitride layer 410a. The silicon oxide layer 410b may be interposed between the first silicon nitride layer 410a and the second silicon nitride layer 410c. In some embodiments, the first silicon nitride layer 410a may contact the second sublayer 400b of the encapsulation layer 400, and the first silicon nitride layer 410a may also contact the insulating layer 104 and the insulating layer 304.

It is worth noting that the silicon oxide layer 410b may be a compressive stress layer, while the first silicon nitride layer 410a and the second silicon nitride layer 410c may be tensile stress layers. Therefore, the composite structure 410 can balance the tensile and compressive stresses, reducing the risk of interface delamination, peeling, or warpage.

In some embodiments, a thickness Tb of the silicon oxide layer 410b is greater than a thickness Ta of the first silicon nitride layer 410a and greater than a thickness Tc of the second silicon nitride layer 410c. In some embodiments, the thickness Ta of the first silicon nitride layer 410a is greater than the thickness Tc of the second silicon nitride layer 410c. Specifically, in some embodiments, the thickness Ta of the first silicon nitride layer 410a may be between 0.1 μm and 0.5 μm (i.e., 0.1 μm ≤ thickness Ta ≤ 0.5 μm), for example, 0.15 μm, 0.2 μm, 0.25 μm, 0.3 μm, 0.35 μm, 0.4 μm, or 0.45 μm. In some embodiments, the thickness Tb of the silicon oxide layer 410b may be between 0.4 μm and 1 μm (i.e., 0.4 μm ≤ thickness Tb ≤ 1 μm), for example, 0.45 μm, 0.5 μm, 0.55 μm, 0.6 μm, 0.65 μm, 0.7 μm, 0.75 μm, 0.8 μm, 0.85 μm, 0.9 μm, or 0.95 μm. In some embodiments, the thickness Tc of the second silicon nitride layer 410c may be between 0.02 μm and 0.15 μm (i.e., 0.02 μm ≤ thickness Tc ≤ 0.15 μm), for example, 0.03 μm, 0.04 μm, 0.05 μm, 0.06 μm, 0.07 μm, 0.08 μm, 0.09 μm, 0.1 μm, 0.11 μm, 0.12 μm, 0.13 μm, or 0.14 μm.

The aforementioned thickness Ta refers to the maximum thickness of the first silicon nitride layer 410a in the normal direction of the first die 100; the thickness Tb refers to the maximum thickness of the silicon oxide layer 410b in the normal direction of the first die 100; and the thickness Tc refers to the maximum thickness of the second silicon nitride layer 410c in the normal direction of the first die 100.

In addition, as shown in FIGS. 1 and FIG. 2D, in some embodiments, the semiconductor package 10 may further include a dummy pad 402. The dummy pad 402 may be disposed between the encapsulation layer 400 and the second die 200, and the encapsulation layer 400 may be disposed between the first die 100 and the structural die 300. In some embodiments, the dummy pad 402 may overlap the encapsulation layer 400 and the second die 200 in the normal direction of the second die 200. In some embodiments, the dummy pad 402 may contact the second sublayer 400b of the encapsulation layer 400, the first silicon nitride layer 410a and the silicon oxide layer 410b of the composite structure 410. In some embodiments, the dummy pad 402 may penetrate the first silicon nitride layer 410a and extend into the silicon oxide layer 410b, but may not contact the second silicon nitride layer 410c.

It is worth noting that during the packaging process, when the first die 100 and the second die 200 are pressed against each other, or when the structural die 300 and the second die 200 are pressed against each other, the configuration of the dummy pad 402 can balance the pressure in the non-die area, thereby reducing the risk of damage or destruction to the structure caused by the packaging process.

In some embodiments, the material of the dummy pad 402 may include a conductive material, such as a metallic conductive material. In some embodiments, the dummy pad 402 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof.

Referring again to FIG. 1, in some embodiments, the semiconductor package 10 may further include a circuit layer 204, a dielectric layer 206, conductive elements 208, and connecting elements. The circuit layer 204 may be disposed on the second interconnection layer 202 and between the dielectric layer 206 and the second interconnection layer 202. The conductive elements 208 may be disposed on the circuit layer 204 and electrically connected to the conductive elements (not shown) in the circuit layer 204. Furthermore, the conductive elements 208 may penetrate the dielectric layer 206 and electrically connect to the connecting elements 210. The connecting elements 210 may be disposed corresponding to the conductive elements 208. That is, in the normal direction of the second die 200, the connecting element 210 may overlap with the conductive element 208. In some embodiments, the connecting elements 210 may further be electrically connected to other external electronic components.

In some embodiments, the circuit layer 204 may have one or more multilayer structures, and may include one or more dielectric layers and patterned conductive layers. In some embodiments, the circuit layer 204 may serve as a redistribution layer (RDL). In some embodiments, the material of the dielectric layer of the circuit layer 204 may include an organic dielectric material, such as polybenzoxazole (PBO), perfluoroalkoxy alkane (PFA), polytetrafluoroethylene (PTFE), fluorinated ethylene propylene (FEP), ABF (Ajinomoto Build-up Film) build-up material, flame-resistant fiberglass (FR4), fiberglass resin composite material, polyimide, benzocyclobutene (BCB), epoxy resin, another suitable dielectric material, or a combination thereof. In accordane with some embodiments, the material of the patterned conductive layer of the circuit layer 204 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof.

In accordane with some embodiments, the material of the dielectric layer 206 may include an inorganic material, an organic material, or a combination thereof. In accordane with some embodiments, the inorganic material may include silicon nitride, silicon oxide, silicon oxynitride, another suitable material, or a combination thereof.In some embodiments, the organic material may include polyimide (PI), photosensitive polyimide (PSPI), polybenzoxazole (PBO), benzocyclobutene (BCB), epoxy, ABF (Ajinomoto Build-up Film) build-up material, another suitable material, or a combination thereof.

In some embodiments, the conductive material of the conductive element 208 may include copper (Cu), titanium (Ti), aluminum (Al), tungsten (W), silver (Ag), gold (Au), tin (Sn), molybdenum (Mo), chromium (Cr), nickel (Ni), platinum (Pt), tantalum (Ta), ruthenium (Ru), alloys of the foregoing metals, another suitable conductive material, or a combination thereof.

In some embodiments, the material of the connecting element 210 may include tin, silver, lead-free tin, copper, nickel, gold, another suitable material, or a combination thereof. In some embodiments, the connecting element 210 may be bonded to various substrates by a reflow process, a fusion bonding process, a hybrid bonding process, a metal-to-metal bonding process, another suitable method, or a combination thereof.

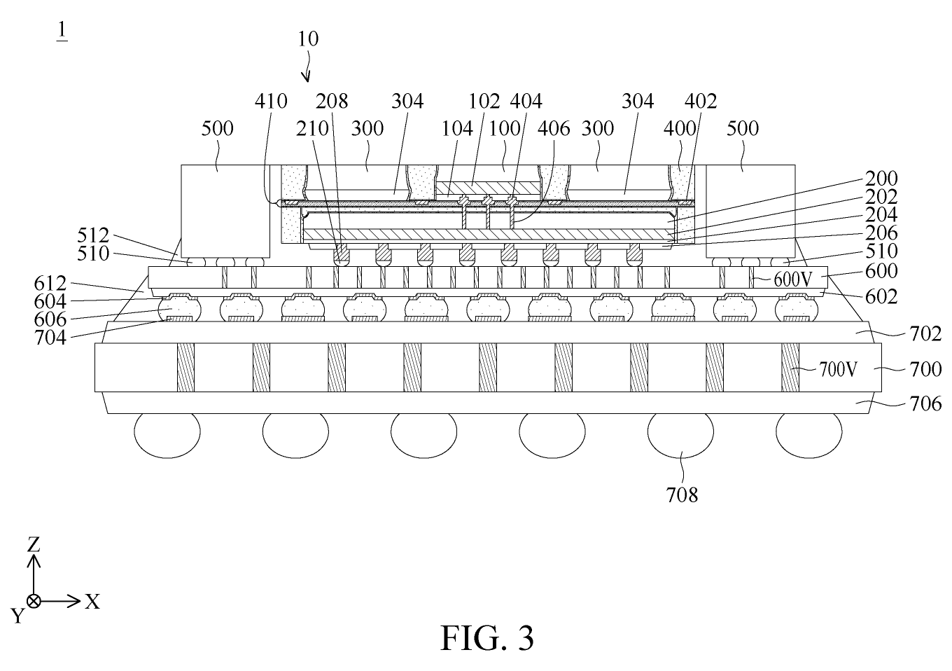

Next, please refer to FIG. 3, which is a cross-sectional diagram of a semiconductor package 1 in some other embodiments of the present disclosure. Specifically, the semiconductor package 1 can be formed based on the structure of the aforementioned semiconductor package 10 and in combination with a suitable package combination. For example, the semiconductor package 1 can be applied to a packaging structure similar to a chip on wafer on substrate (CoWoS).

As shown in FIG. 3, the semiconductor package 1 has the structure of the semiconductor package 10 and may further include a third die 500. The third die 500 may be disposed adjacent to the semiconductor package 10 and may be disposed together with the semiconductor package 10 on the substrate 600. Specifically, the semiconductor package 1 may further include connecting elements 510 and an insulating layer 512. The third die 500 may be electrically connected to conductive elements (not shown) on the substrate 600 through the connecting elements 510. The insulating layer 512 may surround the third die 500 and the semiconductor package 10 and may be disposed between the third die 500 and the substrate 600 and between the semiconductor package 10 and the substrate 600.

The third die 500 may include a known-good die (KGD), an integrated circuit chip (IC), or another suitable electronic component. In some embodiments, the third die 500 may be an auxiliary chip or a control chip. Specifically, in some embodiments, the third die 500 may include a system-on-chip (SoC), a central processing unit (CPU), a graphics processing unit (GPU), an application-specific integrated circuit (ASIC), a dynamic random access memory (DRAM), a high-bandwidth memory (BBM), a photonic integrated circuit (IC), an active component, a passive component, a power management system chip, or another logic integrated circuit. Furthermore, the type of the third die 500 may be the same as or different from that of the first die 100.

In some embodiments, the material of the connecting element 510 may include tin, silver, lead-free tin, copper, nickel, gold, another suitable material, or a combination thereof. In some embodiments, the connecting elements 510 may be bonded to the substrate 600 by a reflow process, a fusion bonding process, a hybrid bonding process, a metal-to-metal bonding process, another suitable method, or a combination thereof.

In some embodiments, the insulating layer 512 may be a encapsulating material or an underfill. In some embodiments, the insulating layer 512 may include a molding compound, an epoxy resin, another suitable encapsulating material, or a combination thereof. Furthermore, the insulating layer 512 may include filler particles, such as silicon oxide, aluminum oxide, titanium oxide, zirconium oxide, silicon carbide, graphene, carbon nanotubes, a combination thereof, or another suitable material.

Furthermore, the semiconductor package 1 may further include a substrate 600, a circuit layer 602, contact pads 604, conductive elements 606, and an insulating layer 612. The circuit layer 602 may be disposed on the substrate 600, the substrate 600 may be disposed between the semiconductor package 10 and the circuit layer 602, and the substrate 600 may be disposed between the third die 500 and the circuit layer 602. The contact pads 604 may be disposed between the circuit layer 602 and the conductive elements 606. The conductive elements 606 may be disposed corresponding to the contact pads 604. That is, in the normal direction of the substrate 600, the conductive element 606 may overlap with the contact pad 604.

The third die 500 may be electrically connected to the conductive elements (not shown) on the substrate 600 thtough the connecting elements 510. The first die 100 and the second die 200 in the semiconductor package 1 may also be electrically connected to the conductive elements (not shown) on the substrate 600 through the connecting elements 210. Furthermore, the substrate 600 has conductive vias 600V. The third die 500 and the first die 100 and the second die 200 in the semiconductor package 1 can be further electrically connected to the circuit layer 602 through the vias 600V, and the contact pads 604 and the conductive elements 606 may be electrically connected to the circuit layer 602.

The substrate 600 may serve as an interposer. In some embodiments, the substrate 600 may include a silicon wafer, quartz, glass, sapphire, or ceramic. In some embodiments, the substrate 600 may be glass and have a conductive via 600V, i.e., a through glass via (TGV) structure.

In some embodiments, the circuit layer 602 may have one or more multilayer structures and may include one or more dielectric layers and patterned conductive layers. In some embodiments, the circuit layer 602 may serve as a redistribution layer (RDL). The materials of the dielectric layer and the patterned conductive layer of the circuit layer 602 may be the same as or similar to those of the aforementioned circuit layer 204 and will not be repeated here.

In some embodiments, the contact pad 604 may include a conductive material, such as a metallic conductive material. In some embodiments, the contact pad 604 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof.

In some embodiments, the material of the conductive element 606 may include tin, silver, lead-free tin, copper, nickel, gold, another suitable material, or a combination thereof.

In some embodiments, the material of the insulating layer 612 may be the same as or similar to that of the aforementioned insulating layer 512, and will not be repeated here.

In addition, as shown in FIG. 3, the semiconductor package 1 may further include a substrate 700, a circuit layer 702, contact pads 704, a circuit layer 706, and connecting elements 708. The substrate 700 and substrate 600 may be disposed on either side of conductive element 606. The circuit layer 702 may be disposed between conductive element 606 and substrate 400, and may be electrically connected to conductive elements 606 via contact pads 704. The conductive elements 606 may be disposed corresponding to contact pads 704. That is, in the normal direction of substrate 600 (e.g., the Z direction in the figure), the conductive element 606 may overlap the contact pad 704. The circuit layer 702 and circuit layer 706 may be disposed on either side of substrate 700, and the circuit layer 702 may be electrically connected to circuit layer 706 through the conductive vias 700V in substrate 700. The connecting elements 708 may be disposed on the circuit layer 706, and the circuit layer 706 may be electrically connected to connecting elements 708. The connecting elements 708 may further be electrically connected to other external electronic components.

In some embodiments, the material of substrate 700 may include silicon wafer, quartz, glass, sapphire, ceramic. In some embodiments, the substrate 700 may be glass and have a conductive via 700V, i.e., a through glass via (TGV) structure.

The circuit layer 702 and the circuit layer 706 may have one or more multilayer structures and may include one or more dielectric layers and patterned conductive layers. In some embodiments, the circuit layer 702 and the circuit layer 706 may serve as a redistribution layer (RDL). The materials of the dielectric layer and patterned conductive layer of the circuit layer 702 and the circuit layer 706 may be the same as or similar to those of the aforementioned circuit layer 204, and will not be repeated here.

In some embodiments, the material of contact pad 704 may be the same as or similar to that of contact pad 604, and will not be repeated here.

In some embodiments, the material of the connecting element 708 may include tin, silver, lead-free tin, copper, nickel, gold, another suitable material, or a combination thereof. In some embodiments, the connecting element 708 may be further bonded to other external electronic components by a reflow process, a fusion bonding process, a hybrid bonding process, a metal-to-metal bonding process, another suitable method, or a combination thereof. For example, the connecting elements 708 may be further electrically connected to a printed circuit board (PCB), a chip, a control element, or another electronic component (not shown), but the present disclosure is not limited thereto.

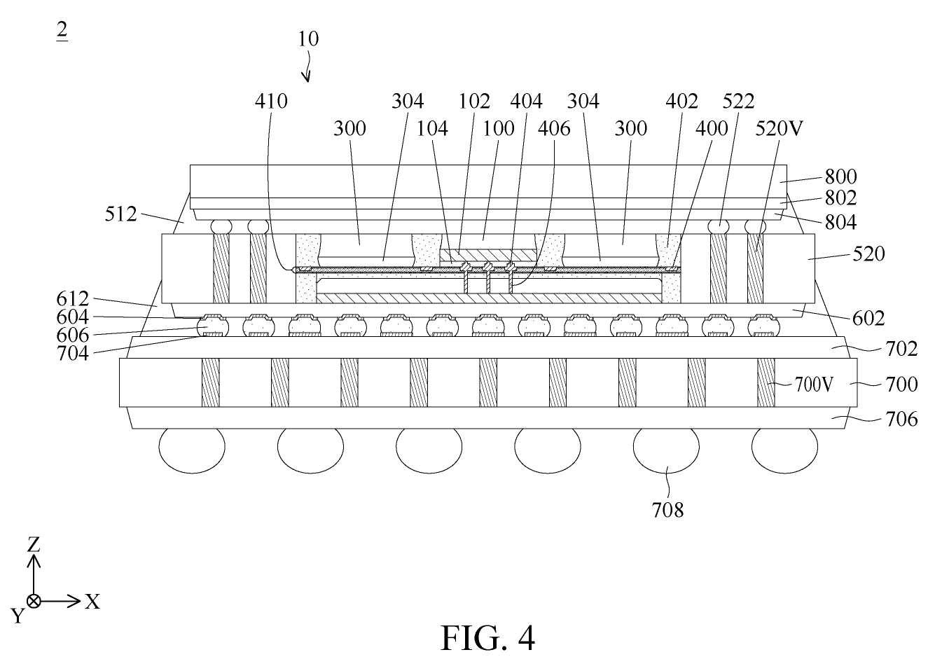

Next, please refer to FIG. 4, which is a cross-sectional diagram of a semiconductor package 2 in some other embodiments of the present disclosure. Specifically, the semiconductor package 2 can be formed based on the structure of the aforementioned semiconductor package 10 and in combination with a suitable package combination. For example, the semiconductor package 2 can be applied to a package structure similar to an integrated fan-out package on package (InFO-PoP).

As shown in FIG. 4, the semiconductor package 2 may further include a fourth die 800, a third interconnection layer 802, and a circuit layer 804. The fourth die 800 may be disposed on the semiconductor package 10, and the third interconnection layer 802 and the circuit layer 804 may be disposed between the fourth die 800 and the semiconductor package 10. Furthermore, the semiconductor package 2 may further include an encapsulation layer 520 and connecting elements 522. The encapsulation layer 520 may surround the semiconductor package 10, and the semiconductor package 10 may be electrically connected to the third interconnection layer 802 and the circuit layer 804 through conductive vias 520V in the encapsulation layer 520 and the connecting elements 522, thereby electrically connecting to the fourth die 800. Furthermore, the insulating layer 512 may surround the fourth die 800 and be disposed between the fourth die 800 and the semiconductor package 10, and between the fourth die 800 and the encapsulation layer 520.

The fourth die 800 may include a known-good die (KGD), an integrated circuit chip (IC), or another suitable electronic component. In some embodiments, the fourth die 800 may include a system-on-a-chip (SoC), a central processing unit (CPU), a graphics processing unit (GPU), an application-specific integrated circuit (ASIC), a dynamic random access memory (DRAM), a high-bandwidth memory (BBM), a photonic integrated circuit (IC), an active component, a passive component, a power management system (PMS) chip, or another logic integrated circuit. Furthermore, the type of the fourth die 800 may be the same as or different from the first die 100 and the second die 200.

The third interconnection layer 802 may include one or more dielectric layers and patterned conductive layers. The materials of the dielectric layer and the patterned conductive layer of the third interconnection layer 802 may be the same or similar to those of the first interconnection layer 102, and will not be repeated here.

The circuit layer 804 may have one or more multilayer structures and may include one or more dielectric layers and patterned conductive layers. In some embodiments, the circuit layer 804 may serve as a redistribution layer (RDL). The materials of the dielectric layer and patterned conductive layer of the circuit layer 804 may be the same or similar to those of the aforementioned circuit layer 204, and will not be repeated here.

The encapsulation layer 520 can reduce the impact of moisture and oxygen on the semiconductor package 2, reduce impact damage to the die and interconnection layers, enhance the mechanical stability of the structure, or provide a heat dissipation path. The encapsulation layer 520 may include a molding compound, epoxy resin, another suitable encapsulating material, or a combination thereof.

In some embodiments, the material of the connecting element 522 may include tin, silver, lead-free tin, copper, nickel, gold, another suitable material, or a combination thereof. In some embodiments, the connecting element 522 may be bonded to the circuit layer 804 by a reflow process, a fusion bonding process, a hybrid bonding process, a metal-to-metal bonding process, another suitable method, or a combination thereof, thereby bonding the fourth die 800 to the semiconductor package 10.

In addition, the semiconductor package 2 may also include the contact pads 604, the conductive elements 606, the substrate 700, the circuit layer 702, the contact pads 704, the circuit layer 706, and the connecting elements 708 of the semiconductor package 1 as shown in FIG. 3, which will not be repeated here.

To summarize the above, according to the embodiments of the present disclosure, the semiconductor package provided includes a specific structural design that can alleviate excessive stress concentration at the interface between different layers during a bonding process (e.g., during reflow soldering), thereby reducing problems such as delamination, peeling, or component cracking at the interface. The structural strength and reliability of the semiconductor package therefore can be improved.

What is claimed is:

1. A semiconductor package, comprising:
a first die comprising a first portion and a second portion, wherein the first portion has a first surface and the second portion has a second surface;
a first interconnection layer disposed on the second surface; and
an encapsulation layer surrounding the first die and the first interconnection layer;
wherein, in a cross-sectional view, the first portion has a first widt at the first surface, the second portion has a second width at an interface between the first portion and the second portion, and the second width is greater than the first width.

2. The semiconductor package as claimed in claim 1, wherein a thickness of the first portion is greater than a thickness of the second portion.

3. The semiconductor package as claimed in claim 1, wherein a difference between the first width and the second width is between 0.1 and 1μm.

4. The semiconductor package as claimed in claim 1, wherein the first portion has a first side surface, the second portion has a second side surface, and the first side surface and the second side surface are disposed between the first surface and the second surface.

5. The semiconductor package as claimed in claim 4, wherein a roughness of the first side surface is greater than a roughness of the second side surface.

6. The semiconductor package as claimed in claim 4, wherein, in a thickness direction, a length of the first side surface is greater than a length of the second side surface.

7. The semiconductor package as claimed in claim 6, wherein the length of the second side surface is between 0.1μm and 1μm

8. The semiconductor package as claimed in claim 4, wherein, in a cross-sectional view, the first side surface has a first end at the first surface and a second end at an interface between the first side surface and the second side surface, and the first end is receded inward with respect to the second end.

9. The semiconductor package as claimed in claim 1, further comprising:
a second die, wherein the first die is disposed thereon; and
a structural die disposed on the second die and adjacent to the first die;
wherein the first die is electrically connected to the second die and the structural die is electrically insulated from the second die.

10. The semiconductor package as claimed in claim 9, further comprising:
a second interconnection layer disposed on a surface of the second die away from the first die, and the first interconnection layer is electrically connected to the second interconnection layer through a conductive via in the second die.

11. The semiconductor package as claimed in claim 9, further comprising:
a first bonding layer disposed on the first interconnection layer and a second bonding layer disposed on a surface of the second die adjacent to the first die, wherein the first bonding layer is directly bonded on the second bonding layer.

12. The semiconductor package as claimed in claim 9, wherein the second die comprises a surface adjacent to the first die and a side surface, and a chamfered corner is formed between the surface and the side surface.

13. The semiconductor package as claimed in claim 12, wherein, in a cross-sectional view, the chamfered corner comprises a curved edge.

14. The semiconductor package as claimed in claim 9, further comprising:
an insulation layer disposed between the structural die and the second die, and the encapsulation layer contacts a side surface of the insulation layer.

15. The semiconductor package as claimed in claim 14, wherein, in a cross-sectional view, the side surface of the insulation layer comprises a first end in contact with the structural die and a second end away from the first end, and the second end is receded inward with respect to the first end.

16. The semiconductor package as claimed in claim 14, wherein the side surface of the insulating layer comprises a first portion connecting the first end and a second portion connecting the second end, and the second portion forms an angle with respect to the first portion.

17. The semiconductor package as claimed in claim 9, further comprising:
a composite structure disposed between the second die and a combination of the first die and the structural die, wherein the composite structure comprises a first silicon nitride layer, a silicon oxide layer, and a second silicon nitride layer, and the second silicon nitride layer is closer to the second die than the first silicon nitride layer.

18. The semiconductor package as claimed in claim 17, wherein a thickness of the silicon oxide layer is greater than a thickness of the first silicon nitride layer and is greater than a thickness of the second silicon nitride layer.

19. The semiconductor package as claimed in claim 17, wherein a thickness of the first silicon nitride layer is greater than a thickness of the second silicon nitride layer.

20. The semiconductor package as claimed in claim 9, further comprising:
a dummy pad disposed between the encapsulation layer and the second die, wherein the encapsulation layer is disposed between the first die and the structural die.
